(19) United States
(12) Patent Application Publication
(10) Pub. No.: US 2024/0220682 A1
(43) Pub. Date: Jul. 4, 2024

(54) ATTRIBUTING SIMULATION GAPS TO INDIVIDUAL SIMULATION COMPONENTS

(71) Applicant: GM Cruise Holdings LLC, San Francisco, CA (US)

(72) Inventors: Hariprasad Govardhanam, Fremont, CA (US); Luke Murchison, Belmont, CA (US); Lynn Sarcione, Austin, TX (US); Jean David Margulici, Oakland, CA (US)

(21) Appl. No.: 18/092,901

(22) Filed: Jan. 3, 2023

(51) Int. Cl. G06F 30/27; B60W 60/00

(52) U.S. Cl. CPC G06F 30/27; B60W 60/0011

(57) ABSTRACT

The disclosed technology provides solutions for improving simulation generation, and in particular for diagnosing problems with a simulation renderer configured to generate simulated (or synthetic) environments for use in autonomous vehicle (AV) testing and training. In some aspects, a process of the disclosed technology includes steps for receiving a set of divergence metrics, wherein the divergence metrics comprise performance statistics for one or more components of a simulation renderer, providing the divergence metrics to a machine-learning model, and identifying, using an attribution tool, one or more components of the simulation renderer that contributed to the AV pose divergence based on one or more weights of the machine-learning model. Systems and machine-readable media are also provided.

### BACKGROUND

### 1. Technical Field

The disclosed technology provides solutions for improving simulation generation, and in particular for diagnosing problems with a simulation renderer configured to generate simulated (or synthetic) environments for use in autonomous vehicle (AV) testing and training.

### 2. Introduction

Autonomous vehicles (AVs) are vehicles having computers and control systems that perform driving and navigation tasks that are conventionally performed by a human driver. As AV technologies continue to advance, they will be increasingly used to improve transportation efficiency and safety. As such, AVs will need to perform many of the functions that are conventionally performed by human drivers, such as performing navigation and routing tasks necessary to provide safe and efficient transportation. Such tasks may require the collection and processing of large quantities of data using various sensor types, including but not limited to cameras, Light Detection and Ranging (LiDAR) sensors, and/or Radio Detection and Ranging (RADAR) disposed on the AV. In some instances, the collected data can be used to generate (or render) simulated (or synthetic/virtual) environments that can be used to perform additional AV testing and training.

### BRIEF DESCRIPTION OF THE DRAWINGS

Certain features of the subject technology are set forth in the appended claims. However, the accompanying drawings, which are included to provide further understanding, illustrate disclosed aspects and together with the description explain the principles of the subject technology. In the drawings:

FIG. 1 is a block diagram of a road-to-simulation (also referred to herein as a road-to-SIM) pipeline that can be configured to receive road data and render synthetic environments used for autonomous vehicle (AV) testing and training, according to some aspects of the disclosed technology.

FIG. 2 conceptually illustrates a block diagram of an example system that can be configured to identify one or more components of a simulation renderer that contribute to simulation divergence, according to some aspects of the disclosed technology.

FIG. 3 illustrates a flow diagram of an example process for identifying one or more components of a simulation renderer that contribute to simulation divergence, according to some aspects of the disclosed technology.

FIG. 4 illustrates an example architecture of a deep-learning neural network that can be implemented at different layers of an AV software stack, according to some aspects of the disclosed technology.

FIG. 5 illustrates an example system environment that can be used to facilitate AV dispatch and operations, according to some aspects of the disclosed technology.

FIG. 6 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form to avoid obscuring certain concepts.

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

The training and testing of an autonomous vehicle (AV) functions can require large quantities of training data. However, it can be difficult to generate necessary quantities of training data through sensor data collection in real-world driving scenarios. To overcome these limitations, AV training and testing can be performed in a simulated (also: simulated or synthetic) environment (e.g., a virtual environment) that emulates real-world objects and scenarios that may be encountered by an AV. For example, the simulated environment can include recreations of environmental features such as roadways, intersections, buildings, etc., as well as dynamic entities, such as other traffic participants (e.g., vehicles) and/or pedestrians, etc. As such, the simulated environment can be used to replicate navigation scenarios and/or encounters that may be experienced by an AV when operating in the real-world. As discussed in further detail below, such simulations can be used to perform AV training and testing; the resulting improvements can then be used to update the AV software stack, thereby improving AV performance, comfort, and safety during real-world operation.

One constraint in using simulated environments for AV training and testing applications is that it can be difficult to accurately recreate real-world scenarios in the simulated environment. That is, a given simulated environment (or SIM environment) may differ or diverge from the real-world environment represented by the road data. The various ways in which characteristics of the SIM environment may differ from those of the real-world environment can be numerous and difficult to intuit by human observers.

In some instances, divergences between a SIM and corresponding real-world environment can be based on differences in object and/or feature placement, and/or other differences in object characteristics. For example, real-world objects represented in road data may be incorrectly rendered and/or incorrectly placed in the simulated environment such that they have different appearance, location, and/or pose characteristics in the SIM environment as compared to the real-world. In some instances, divergences between a SIM and corresponding real-world environment can be based on differences in how AV behaviors and/or AV systems are modeled in SIM as compared to the performance of analogous behaviors/systems in the real-world. For example, physical AV sensors (e.g., LiDAR, camera and/or RADAR sensors etc.) used to collect real-world road data may be inaccurately (or incompletely) emulated in the SIM environment, resulting in differences in how objects are perceived in the SIM environment as compared to the real-world. Similarly, compute characteristics of a virtual (simulated) AV operating in the SIM environment may be modeled in a manner that deviates from how compute resources (e.g., compute nodes, compute graphs, etc.) perform on physical AVs navigating the real-world environment.

Deviations in how characteristics of the real-world and/or characteristics of a real-world AV are emulated in the SIM environment (referred to herein as simulation divergence/s) can result in significant and complex aberrations in AV performance in the SIM environment. For example, simulation divergence can result in differences in outputs at different layers of the AV software stack (e.g., the perception layer, prediction layer and/or planning layer), thereby compounding into divergences in resulting AV behaviors (e.g., implemented at the control layer), such as AV trajectory, kinematics and/or pose. As used herein, such differences affecting AV kinematics and/or trajectories are referred to as pose divergence/s or AV pose divergence/s.

In some instances, the simulation divergences can result from errors or inadequacies of discrete components or sub-systems of the simulation renderer. As discussed in further detail below, the various aspects of SIM environment creation and rendering can be handled, at least in part, by different components or subsystems of a rendering module (also referred to herein as a simulation renderer). To improve the performance of the simulation renderer, it would be helpful to have tools and processes for identifying root causes of simulation divergence based on a given set of road data, such as by identifying contributions of each component of the simulation renderer to a resulting simulation and/or AV pose divergence.

Aspects of the disclosed technology provide solutions for improving the fidelity of rendered simulated environments by facilitating the identification of various components and/or subsystems in the rendering pipeline, as well as how those components contribute to measured simulation divergences and/or resulting AV pose divergence.

In some aspects, machine-learning models may be used to identify individual error contributions by one or more components (e.g., components of a simulation renderer) and/or other subsystems of the rendering pipeline, as well as how those components contribute to the resulting AV pose divergence. As discussed in further detail below, attributing simulation and/or AV pose divergence errors to specific components/subsystems can be performed by an attribution tool (or attribution module) that is configured to examine various weights of a machine-learning model that is configured to receive divergence metrics from various components or subsystem (e.g., of a simulation renderer) and to make divergence estimates based on the received divergence metrics. As used herein, divergence metrics for any given component or subsystem can be used to describe or quantify differences between specific environmental characteristics and/or objects of a real-world scenario (e.g., as represented in road data) and the resulting characteristics or objects, as rendered in the simulated environment.

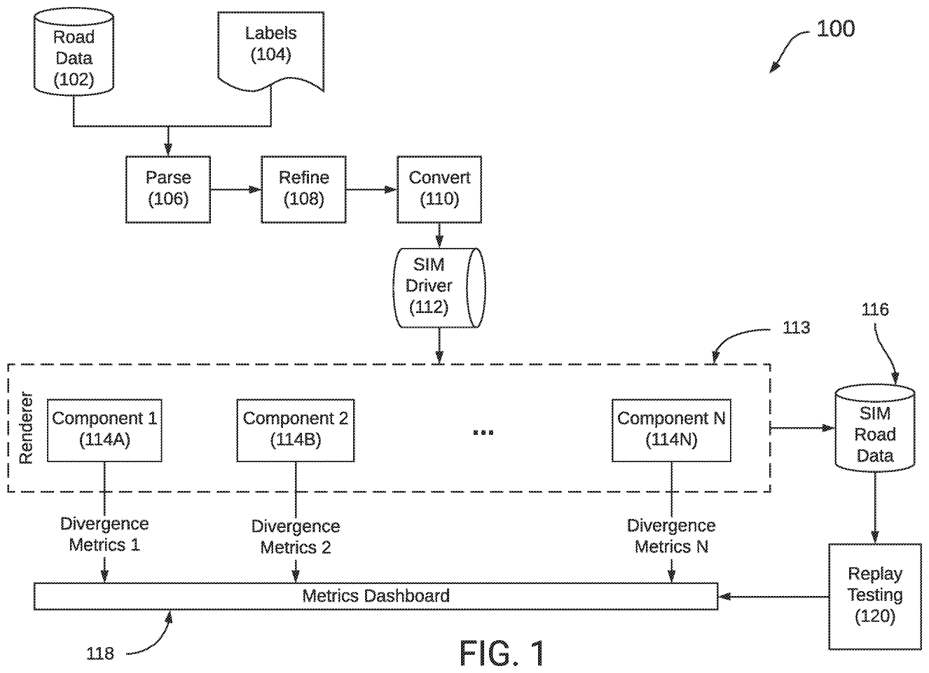

FIG. 1 is a block diagram of a road-to-simulation (or road-to-SIM) pipeline 100 that can be configured for receiving road data and rendering synthetic environments used for autonomous vehicle (AV) testing and training. Pipeline 100 can include a database of road data 102 that can include AV sensor data collected by one or more AVs during the course of driving operations. As such, road data 102 can include various types of sensor data, including but not limited to: Light Detection and Ranging (LiDAR) data, Radio Detection and Ranging (RADAR) data, camera data, accelerometer data, ultrasonic sensor data, and the like. As such, road data 102 can include sensor data and other metadata (e.g., location metadata and/or map metadata) describing an environment encountered by the collecting AV while performing driving operations. Road data from database 102 can be augmented with one or more labels 104, for example, that provide metadata and/or semantic labels for various objects, entities, and/or entity behaviors represented in the road data 102. For example, labels 104 can supply object attribute information (e.g., length, width, height, etc.), as well as information indicating object relationships (e.g., a pedestrian pushing a stroller, or walking a dog, etc.).

Once the road data 102 has been augmented with labels 104, the labeled road data can be parsed (106), refined (108) and converted (110) into a data format, such as a markup language format, before being provided to renderer 113, via simulation driver 112 to renderer 113. More specifically, parsing (106) can be performed to extract objects from road data 102 (and/or from labels 104) for selection and placement in the simulated environment. The refinement process (108) can be performed to apply filters, for example, to exclude unimportant objects or other artifacts, and to modify object attributes and/or entity behaviors based on realism checks.

Once received at renderer 113, the refined and converted road data can be rendered into simulated (or synthetic) scene data, for example, and output as simulated (SIM) road data 116. That is, SIM road data 116 represents a simulated/synthetic representation of the real-world scene described by road data 102 and/or labels 104.

Various characteristics or sensor modalities of SIM road data 116 (e.g., object appearance and placement, atmospheric effects, etc.), can be rendered by discrete subsystems or components 114 of renderer 113. By way of example, separate components, e.g., Component 1 114A, Component 2 114B . . . Component N 114 N, (collectively components 114), of the renderer 113 can be responsible for emulating the appearance and/or placement of real-world objects (represented in road data 102) by replicating them in the synthetic scene (represented by SIM road data 116). Similarly, components 114 can perform rendering necessary to emulate the behavior of various real-world entities, and/or various autonomous vehicle (AV) systems or functions (e.g., AV sensors and/or compute capabilities), in the synthetic scene. Additionally, components 114 may be configured for rendering effects in the synthetic scene, such as atmospheric and/or lighting effects (e.g., fog, clouds, rain, etc.).

When rendering is performed using received road data 102, e.g., to produce SIM road data 116, divergence metrics can be calculated/determined for various tasks performed by each of components 114. The divergence metrics provide an indication as to how well a given component emulates or renders real-world characteristics represented in road data 102. That is, the divergence metrics provide a quantitative (or qualitative) indication of an amount divergence between how real-world characteristics (e.g., AV sensor data, object placements, AV compute capabilities, etc.) are represented in road data 102, and how the corresponding characteristics are rendered by the associated component. For example, if Component 1 114A is configured to emulate/simulate real-world LiDAR sensor data in the SIM environment (represented in SIM road data 116), then the associated divergence metrics (e.g., Divergence Metrics 1) can indicate an amount of difference (divergence) between the LiDAR data represented in road data 102, and the simulated LiDAR data generated by Component 1 114A. Similarly, if Component 2 114B is configured to emulate/simulate real-world atmospheric events in the SIM environment, then the associated divergence metrics (e.g., Divergence Metrics 2) can indicate an amount of difference (divergence) between the atmospheric events represented in road data 102, and the simulated atmospheric events generated by Component 2 114B.

Divergence metrics generated by components 114 can be provided to a metrics dashboard 118, for example to provide visual feedback to a user or operator regarding the performance of one or more of components 114. Metrics dashboard 118 can also receive outputs from a replay testing process 120, which simulates AV behavior in the simulated environment using SIM road data 116. As such, metrics dashboard 118 can provide feedback displays to indicate the fidelity of the SIM environment (with respect to the real-world environment), as well as AV performance in the SIM environment. By way of example, metrics dashboard 118 can indicate an overall pose divergence of the AV in the SIM environment as compared to the real-world environment.

As discussed above, divergence metrics for each component 114 of renderer 113 can be used to predict an aggregate resulting AV pose divergence. For example, a resulting AV pose divergence can represent a difference in AV trajectory, pose, and/or other kinematic characteristics, as between the real-world environment, and AV performance in the simulated environment, e.g., as determined through replay testing 120.

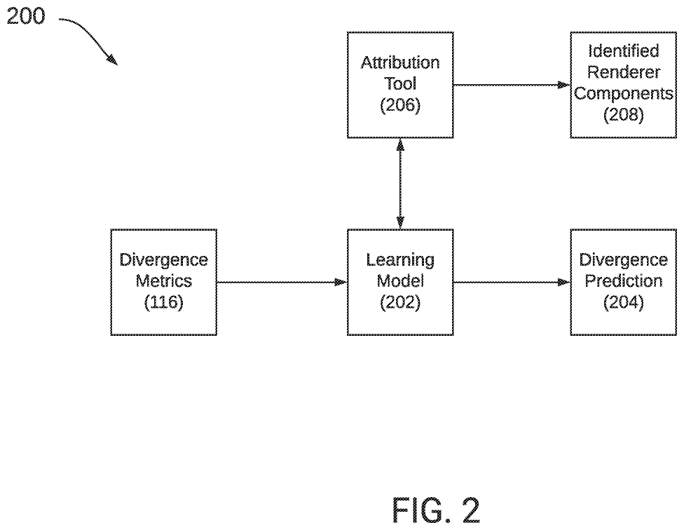

In some aspects, AV pose divergences can be predicted based on divergence metrics 116, using a machine-learning model. Although different types of machine-learning models may be used, it can be easier to identify the contributions of individual subsystems, such as components 114, when using an intuitive (or interpretable) ML model, such as a regressor, a random forest, or a convolutional neural-network (CNN). Further details regarding the use of predictive models for identifying AV pose divergence contributions are provided in further detail with respect to FIG. 2, below.

FIG. 2 conceptually illustrates a block diagram of an example system 200 that can be configured to facilitate the identification of one or more components of a simulation renderer (e.g., renderer 113 of FIG. 1) that contribute to simulation divergence. System 200 includes a learning model 202 that is configured to receive divergence metrics 116 from one or more rendering system subsystems (e.g., components 114) and to make divergence predictions 204. As used herein, divergence predictions 204 can include predictions about divergences in any resulting simulation and/or AV characteristics (also referred to herein as divergence estimates) based on the divergence metrics 116. By way of example, divergence predictions 204 can include estimates/predictions about divergences in AV pose, AV trajectory, and/or in AV kinematic properties (speed, velocity, acceleration, etc.), at different times during AV operation. Divergence predictions can also include divergences in system performance, e.g., measurements, at different layers of the AV stack. By way of example, divergence predictions 204 may include estimates in differences in object tracking (e.g., performed by a prediction layer of the AV stack), as between the real-world and simulated environments.

To better understand the impact divergence metrics 116 from different components 114 have on the resulting divergence prediction 204, learning model 202 can be inspected by an attribution tool 206 that is configured to identify weights at various layers of learning model 202. That is, attribution tool 206 can be configured to examine weights at various layers of learning model 202 to determine how the various components of the rendering pipeline, such as renderer 113 discussed above with respect to FIG. 1, contribute to the overall divergence predictions 204. By way of example, attribution tool 206 can be configured to identify one or more of components 114 that contribute most significantly to the predicted divergence prediction 204 (e.g., overall divergence in AV pose, trajectory, and/or AV kinematics, etc.). In some cases, attribution tool 206 can be configured to identify (or determine) relative proportions of component contribution. By way of example, the attribution tool 206 may determine that a LiDAR sensor rendering component contributed to 50% of the predicted AV divergence 204, whereas an atmospherics component, responsible for rendering atmospheric effects in the SIM environment, contributed to 30% of the predicted AV pose divergence 204.

In some aspects, attribution tool 206 may be configured to identify specific rendering components that contribute to overall divergence above a specified predetermined threshold. By way of example, attribution tool 206 may be configured to identify individual components that supply a greater than 5%, 20%, or 50% contribution to overall divergence. Depending on the desired implementation, contribution thresholds may be set a different predefined proportions or amounts, for example, depending on the type of divergence being estimated by divergence prediction 204, and/or based on user-defined parameters.

As discussed above, the function of attribution tool 206 can be facilitated by the selection of model architectures in which layer features can be more easily or intuitively correlated to specific components and/or divergence metric types. For example, attribution tool 206 may perform more accurately if learning model 202 is a low complexity model, such as a regression model, random forest, convolutional neural network, or the like. That is, learning model 202 may be configured to be interpretable by attribution tool 206.

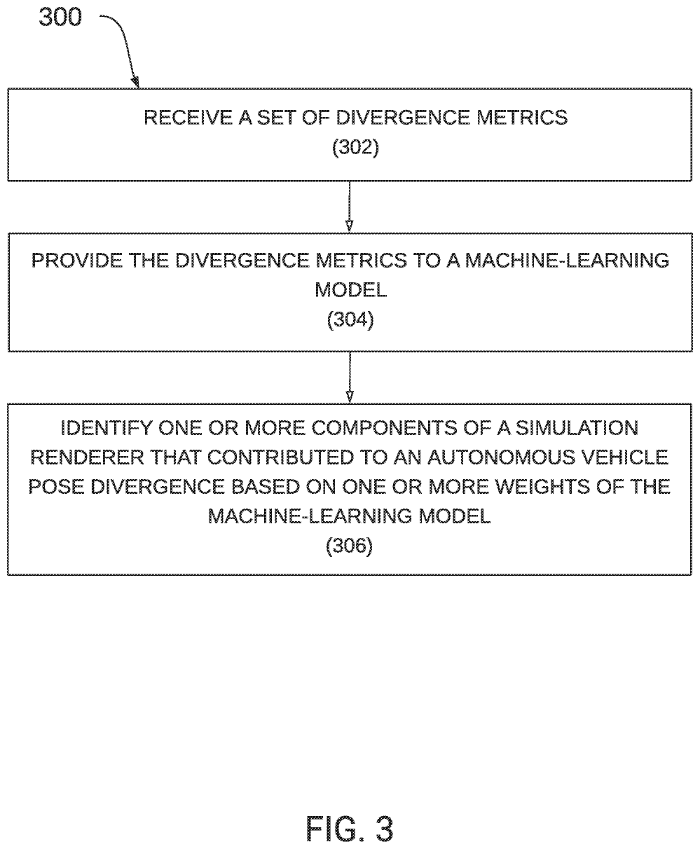

FIG. 3 illustrates a flow diagram of an example process 300 for identifying one or more components of a simulation renderer that contribute to simulation divergence, according to some aspects of the disclosed technology. At step 302, process 300 includes receiving a set of divergence metrics, wherein the divergence metrics comprise performance statistics for one or more components of a simulation renderer. The divergence metrics can be received from the one or more components of the simulation renderer. For example, the simulation renderer can include a sensor component configured to simulate one or more real-world autonomous vehicle (AV) sensors in the simulated environment. In other aspects, the simulation renderer may include an atmospherics component that is configured to simulate atmospheric weather events in the simulated environment.

As discussed above, the divergence metrics provide an indication as to how well a given component emulates or renders real-world characteristics represented in road data. That is, the divergence metrics provide a quantitative (or qualitative) indication of an amount divergence between how real-world characteristics (e.g., AV sensor data, object placements, AV compute capabilities, etc.) are represented in road data 102, and how the corresponding characteristics are rendered by the associated component. As such, performance statistics may indicate a degree of fidelity (or agreement) between real-world and SIM representations for a given divergence metric. By way of example, divergence metrics for a component configured to model real-world (physical) AV sensors (such as a LiDAR sensor module), may indicate an amount (or degree) of correspondence between real-world point-cloud data and the resulting (SIM) point cloud data generated in the SIM environment, e.g., an 5% correspondence, a 15%, or an 82% correspondence, etc.

At step 304, process 300 includes providing the divergence metrics to a machine-learning model, wherein the machine-learning model is trained to predict an autonomous vehicle (AV) pose divergence in a simulated environment based on the divergence metrics. In some aspects, the AV pose divergence can be (or can include) a distance between a first trajectory for an AV that is represented in road data and a second trajectory for the AV that is represented in a simulated environment. In some aspects, the machine-learning model may be (or may include) a regression model, a random forest, a classifier, a decision tree, or a combination thereof.

At step 306, process 300 includes identifying, using an attribution tool, one or more components of the simulation renderer that contributed to the AV pose divergence based on one or more weights of the machine-learning model. As discussed above, the function of attribution tool can be facilitated by the selection of model architectures in which layer features can be more easily or intuitively correlated to specific components and/or divergence metric types. For example, the attribution tool may perform more accurately if machine-learning model (e.g., learning model 202) is a low complexity model, such as a regression model, random forest, convolutional neural network, or the like.

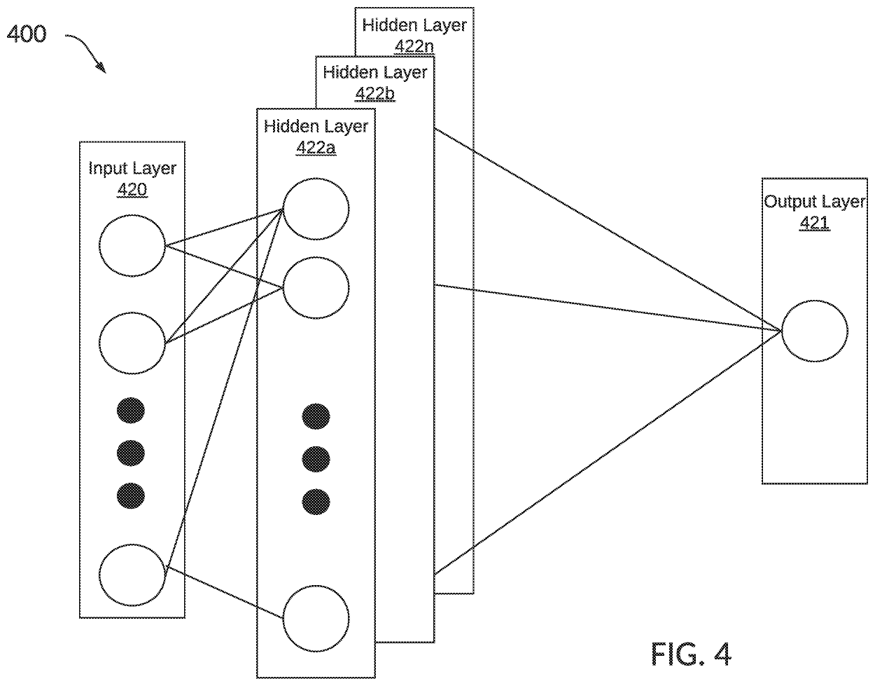

FIG. 4 illustrates an example architecture of a deep-learning neural network 400 that can be implemented at different layers of an AV software stack. By way of example, neural network 400 may be configured to perform functions relating to object detection and identification (e.g., as part of the AV perception layer), and/or functions relating to object tracking (e.g., as part of the AV prediction layer), etc. In one illustrative example, the input layer 420 can be configured to receive sensor data associated with a given AV sensor modality, such as a LiDAR sensor, a RADAR sensor, or a camera sensor, etc. The neural network 400 includes multiple hidden layers 422a, 422b, through 422n. The hidden layers 422a, 422b, through 422n include “n” number of hidden layers, where “n” is an integer greater than or equal to one. The number of hidden layers can be made to include as many layers as needed for the given application. The neural network 400 further includes an output layer 421 that provides an output resulting from the processing performed by the hidden layers 422a, 422b, through 422n.

The neural network 400 is a multi-layer neural network of interconnected nodes. Each node can represent a piece of information. Information associated with the nodes is shared among the different layers and each layer retains information as information is processed. In some cases, the neural network 400 can include a feed-forward network, in which case there are no feedback connections where outputs of the network are fed back into itself. In some cases, the neural network 400 can include a recurrent neural network, which can have loops that allow information to be carried across nodes while reading in input.

Information can be exchanged between nodes through node-to-node interconnections between the various layers. Nodes of the input layer 420 can activate a set of nodes in the first hidden layer 422a. For example, as shown, each of the input nodes of the input layer 420 is connected to each of the nodes of the first hidden layer 422a. The nodes of the first hidden layer 422a can transform the information of each input node by applying activation functions to the input node information. The information derived from the transformation can then be passed to and can activate the nodes of the next hidden layer 422b, which can perform their own designated functions. Example functions include convolutional, up-sampling, data transformation, and/or any other suitable functions. The output of the hidden layer 422b can then activate nodes of the next hidden layer, and so on. The output of the last hidden layer 422n can activate one or more nodes of the output layer 421, at which an output is provided. In some cases, while nodes (e.g., node 426) in the neural network 400 are shown as having multiple output lines, a node can have a single output and all lines shown as being output from a node represent the same output value.

In some cases, each node or interconnection between nodes can have a weight that is a set of parameters derived from the training of the neural network 400. Once the neural network 400 is trained, it can be referred to as a trained neural network, which can be used to classify one or more activities. For example, an interconnection between nodes can represent a piece of information learned about the interconnected nodes. The interconnection can have a tunable numeric weight that can be tuned (e.g., based on a training dataset), allowing the neural network 400 to be adaptive to inputs and able to learn as more and more data is processed.

Neural network 400 is pre-trained to process the features from the data in the input layer 420 using the different hidden layers 422a, 422b, through 422n in order to provide the output through the output layer 421. In some cases, the neural network 400 can adjust the weights of the nodes using a training process called backpropagation. As noted above, a backpropagation process can include a forward pass, a loss function, a backward pass, and a weight update. The forward pass, loss function, backward pass, and parameter update is performed for one training iteration. The process can be repeated for a certain number of iterations for each set of training data until the neural network 400 is trained well enough so that the weights of the layers are accurately tuned.

A loss function can be used to analyze error in the output. Any suitable loss function definition can be used, such as a Cross-Entropy loss. Another example of a loss function includes the mean squared error (MSE), defined as

$$E\_total = \sum ( \frac{1}{2} {( target - output )}^{2} ) .$$

The loss can be set to be equal to the value of E total. The goal of training is to minimize the amount of loss so that the predicted output is the same as the training label. The neural network 400 can perform a backward pass by determining which inputs (weights) most contributed to the loss of the network and can adjust the weights so that the loss decreases and is eventually minimized. A derivative of the loss with respect to the weights (denoted as dL/dW, where W are the weights at a particular layer) can be computed to determine the weights that contributed most to the loss of the network. After the derivative is computed, a weight update can be performed by updating all the weights of the filters. For example, the weights can be updated so that they change in the opposite direction of the gradient. The weight update can be denoted as w=w_i−η dL/dW, where w denotes a weight, wi denotes the initial weight, and f denotes a learning rate. The learning rate can be set to any suitable value, with a high learning rate including larger weight updates and a lower value indicating smaller weight updates.

The neural network 400 can include any suitable deep network. One example includes a convolutional neural network (CNN), which includes an input layer and an output layer, with multiple hidden layers between the input and out layers. The hidden layers of a CNN include a series of convolutional, nonlinear, pooling (for downsampling), and fully connected layers. The neural network 400 can include any other deep network other than a CNN, such as an autoencoder, a deep belief nets (DBNs), a Recurrent Neural Networks (RNNs), among others.

As understood by those of skill in the art, machine-learning based classification techniques can vary depending on the desired implementation. For example, machine-learning classification schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

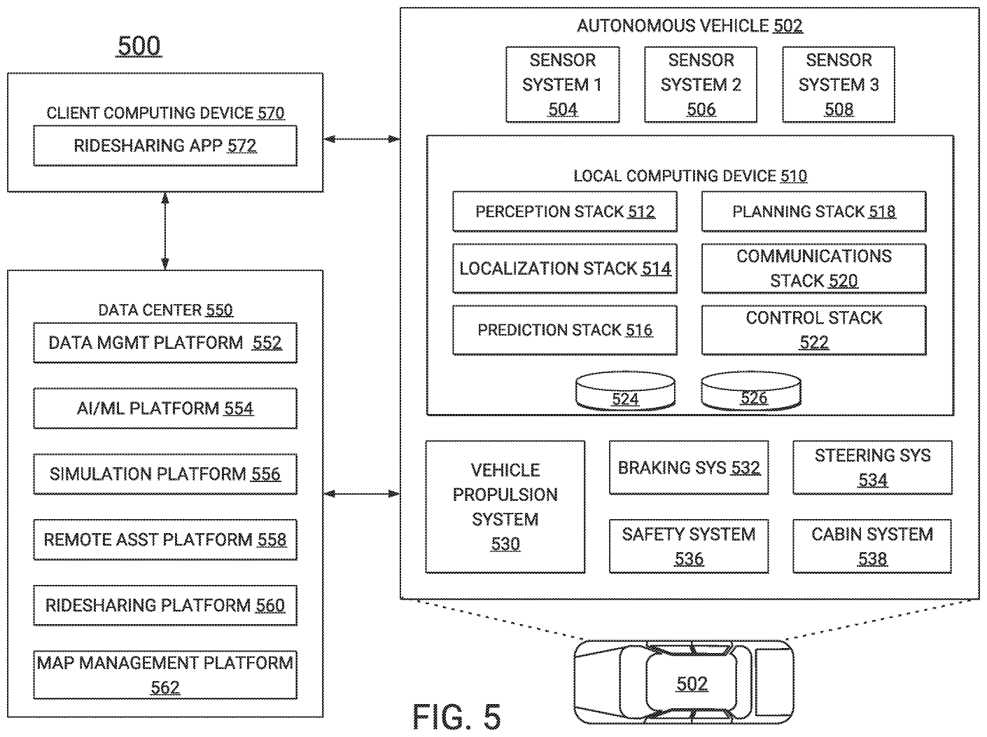

FIG. 5 illustrates an example of an AV management system 500. One of skill in the art will understand that, for the AV management system 500 and any system discussed in the present disclosure, there can be additional or fewer components in similar or alternative configurations. The illustrations and examples provided in the present disclosure are for conciseness and clarity. Other embodiments may include different numbers and/or types of elements, but one of skill the art will appreciate that such variations do not depart from the scope of the present disclosure.

In this example, the AV management system 500 includes an AV 502, a data center 150, and a client computing device 170. The AV 502, the data center 550, and the client computing device 570 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 502 can navigate roadways without a human driver based on sensor signals generated by multiple sensor systems 504, 506, and 508. The sensor systems 504-508 can include different types of sensors and can be arranged about the AV 502. For instance, the sensor systems 504-508 can comprise Inertial Measurement Units (IMUs), cameras (e.g., still image cameras, video cameras, etc.), optical sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 504 can be a camera system, the sensor system 506 can be a LIDAR system, and the sensor system 508 can be a RADAR system. Other embodiments may include any other number and type of sensors.

The AV 502 can also include several mechanical systems that can be used to maneuver or operate the AV 502. For instance, the mechanical systems can include a vehicle propulsion system 530, a braking system 532, a steering system 534, a safety system 536, and a cabin system 538, among other systems. The vehicle propulsion system 530 can include an electric motor, an internal combustion engine, or both. The braking system 532 can include an engine brake, brake pads, actuators, and/or any other suitable componentry configured to assist in decelerating the AV 502. The steering system 534 can include suitable componentry configured to control the direction of movement of the AV 502 during navigation. The safety system 536 can include lights and signal indicators, a parking brake, airbags, and so forth. The cabin system 538 can include cabin temperature control systems, in-cabin entertainment systems, and so forth. In some embodiments, the AV 502 might not include human driver actuators (e.g., steering wheel, handbrake, foot brake pedal, foot accelerator pedal, turn signal lever, window wipers, etc.) for controlling the AV 502. Instead, the cabin system 538 can include one or more client interfaces (e.g., Graphical User Interfaces (GUIs), Voice User Interfaces (VUIs), etc.) for controlling certain aspects of the mechanical systems 530-538.

The AV 502 can additionally include a local computing device 510 that is in communication with the sensor systems 504-508, the mechanical systems 530-538, the data center 550, and the client computing device 570, among other systems. The local computing device 510 can include one or more processors and memory, including instructions that can be executed by the one or more processors. The instructions can make up one or more software stacks or components responsible for controlling the AV 502; communicating with the data center 550, the client computing device 570, and other systems; receiving inputs from riders, passengers, and other entities within the AV's environment; logging metrics collected by the sensor systems 504-508; and so forth. In this example, the local computing device 510 includes a perception stack 512, a mapping and localization stack 514, a prediction stack 516, a planning stack 518, a communications stack 520, a control stack 522, an AV operational database 524, and an HD geospatial database 526, among other stacks and systems.

The perception stack 512 can enable the AV 502 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 504-508, the mapping and localization stack 514, the HD geospatial database 526, other components of the AV, and other data sources (e.g., the data center 550, the client computing device 570, third party data sources, etc.). The perception stack 512 can detect and classify objects and determine their current locations, speeds, directions, and the like. In addition, the perception stack 512 can determine the free space around the AV 502 (e.g., to maintain a safe distance from other objects, change lanes, park the AV, etc.). Perception stack 512 can also identify environmental uncertainties, such as where to look for moving objects, flag areas that may be obscured or blocked from view, and so forth. In some embodiments, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

Mapping and localization stack 514 can determine the AV's position and orientation (pose) using different methods from multiple systems (e.g., GPS, IMUs, cameras, LIDAR, RADAR, ultrasonic sensors, the HD geospatial database 526, etc.). For example, in some embodiments, AV 502 can compare sensor data captured in real-time by sensor systems 504-508 to data in HD geospatial database 526 to determine its precise (e.g., accurate to the order of a few centimeters or less) position and orientation. AV 502 can focus its search based on sensor data from one or more first sensor systems (e.g., GPS) by matching sensor data from one or more second sensor systems (e.g., LIDAR). If the mapping and localization information from one system is unavailable, AV 502 can use mapping and localization information from a redundant system and/or from remote data sources.

Prediction stack 516 can receive information from localization stack 514 and objects identified by perception stack 512 and predict a future path for the objects. In some embodiments, prediction stack 516 can output several likely paths that an object is predicted to take along with a probability associated with each path. For each predicted path, prediction stack 516 can also output a range of points along the path corresponding to a predicted location of the object along the path at future time intervals along with an expected error value for each of the points that indicates a probabilistic deviation from that point.

Planning stack 518 can determine how to maneuver or operate AV 502 safely and efficiently in its environment. For example, planning stack 518 can receive the location, speed, and direction of AV 502, geospatial data, data regarding objects sharing the road with AV 502 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 502 from one point to another and outputs from the perception stack 512, localization stack 514, and prediction stack 516. Planning stack 518 can determine multiple sets of one or more mechanical operations that AV 502 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 518 can select from multiple backup plans to carry out. For example, while preparing to change lanes to turn right at an intersection, another vehicle may aggressively cut into the destination lane, making the lane change unsafe. The planning stack 518 could have already determined an alternative plan for such an event. Upon its occurrence, it could help direct AV 502 to go around the block instead of blocking a current lane while waiting for an opening to change lanes.

Control stack 522 can manage the operation of the vehicle propulsion system 530, the braking system 532, the steering system 534, the safety system 536, and the cabin system 538. Control stack 522 can receive sensor signals from the sensor systems 504-508 as well as communicate with other stacks or components of the local computing device 510 or a remote system (e.g., the data center 550) to effectuate operation of AV 502. For example, control stack 522 can implement the final path or actions from the multiple paths or actions provided by planning stack 518. This can involve turning the routes and decisions from planning stack 518 into commands for the actuators that control the AV's steering, throttle, brake, and drive unit.

Communications stack 520 can transmit and receive signals between the various stacks and other components of AV 502 and between AV 502, data center 550, client computing device 570, and other remote systems. Communications stack 520 can enable the local computing device 510 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). Communications stack 520 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

HD geospatial database 526 can store HD maps and related data of the streets upon which the AV 502 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

AV operational database 524 can store raw AV data generated by the sensor systems 504-508, stacks 512-522, and other components of AV 502 and/or data received by AV 502 from remote systems (e.g., data center 550, client computing device 570, etc.). In some embodiments, the raw AV data can include HD LIDAR point cloud data, image data, RADAR data, GPS data, and other sensor data that data center 550 can use for creating or updating AV geospatial data or for creating simulations of situations encountered by AV 502 for future testing or training of various machine learning algorithms that are incorporated in local computing device 510.

Data center 550 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. Data center 550 can include one or more computing devices remote to local computing device 510 for managing a fleet of AVs and AV-related services. For example, in addition to managing AV 502, data center 550 may also support a ridesharing service, a delivery service, a remote/roadside assistance service, street services (e.g., street mapping, street patrol, street cleaning, street metering, parking reservation, etc.), and the like.

Data center 550 can send and receive various signals to and from AV 502 and client computing device 570. These signals can include sensor data captured by the sensor systems 504-508, roadside assistance requests, software updates, ridesharing pick-up and drop-off instructions, and so forth. In this example, data center 550 includes a data management platform 552, an Artificial Intelligence/Machine Learning (AI/ML) platform 554, a simulation platform 556, a remote assistance platform 558, and a ridesharing platform 560, and a map management platform 562, among other systems.

Data management platform 552 can be a “big data” system capable of receiving and transmitting data at high velocities (e.g., near real-time or real-time), processing a large variety of data and storing large volumes of data (e.g., terabytes, petabytes, or more of data). The varieties of data can include data having different structured (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 550 can access data stored by the data management platform 552 to provide their respective services.

AI/ML platform 554 can provide the infrastructure for training and evaluating machine learning algorithms for operating AV 502, the simulation platform 556, the remote assistance platform 558, the ridesharing platform 560, the map management platform 562, and other platforms and systems. Using the AI/ML platform 554, data scientists can prepare data sets from the data management platform 552; select, design, and train machine learning models; evaluate, refine, and deploy the models; maintain, monitor, and retrain the models; and so on.

Simulation platform 556 can enable testing and validation of the algorithms, machine learning models, neural networks, and other development efforts for AV 502, remote assistance platform 558, ridesharing platform 560, map management platform 562, and other platforms and systems. The simulation platform 556 can replicate a variety of driving environments and/or reproduce real-world scenarios from data captured by AV 502, including rendering geospatial information and road infrastructure (e.g., streets, lanes, crosswalks, traffic lights, stop signs, etc.) obtained from a cartography platform (e.g., map management platform 562); modeling the behavior of other vehicles, bicycles, pedestrians, and other dynamic elements; simulating inclement weather conditions, different traffic scenarios; and so on.

Remote assistance platform 558 can generate and transmit instructions regarding the operation of the AV 502. For example, in response to an output of the AI/ML platform 554 or other system of data center 550, remote assistance platform 558 can prepare instructions for one or more stacks or other components of AV 502.

Ridesharing platform 560 can interact with a customer of a ridesharing service via a ridesharing application 572 executing on client computing device 570. The client computing device 570 can be any type of computing system, including a server, desktop computer, laptop, tablet, smartphone, smart wearable device (e.g., smartwatch, smart eyeglasses or other Head-Mounted Display (HMD), smart ear pods, or other smart in-ear, on-ear, or over-ear device, etc.), gaming system, or other general purpose computing device for accessing ridesharing application 572. Client computing device 570 can be a customer's mobile computing device or a computing device integrated with the AV 502 (e.g., the local computing device 510). The ridesharing platform 560 can receive requests to pick up or drop off from the ridesharing application 572 and dispatch the AV 502 for the trip.

Map management platform 562 can provide a set of tools for the manipulation and management of geographic and spatial (geospatial) and related attribute data. The data management platform 552 can receive LIDAR point cloud data, image data (e.g., still image, video, etc.), RADAR data, GPS data, and other sensor data (e.g., raw data) from one or more AVs 502, Unmanned Aerial Vehicles (UAVs), satellites, third-party mapping services, and other sources of geospatially referenced data. The raw data can be processed, and map management platform 562 can render base representations (e.g., tiles (2D), bounding volumes (3D), etc.) of the AV geospatial data to enable users to view, query, label, edit, and otherwise interact with the data. Map management platform 562 can manage workflows and tasks for operating on the AV geospatial data. Map management platform 562 can control access to the AV geospatial data, including granting or limiting access to the AV geospatial data based on user-based, role-based, group-based, task-based, and other attribute-based access control mechanisms. Map management platform 562 can provide version control for the AV geospatial data, such as to track specific changes that (human or machine) map editors have made to the data and to revert changes when necessary. Map management platform 562 can administer release management of the AV geospatial data, including distributing suitable iterations of the data to different users, computing devices, AVs, and other consumers of HD maps. Map management platform 562 can provide analytics regarding the AV geospatial data and related data, such as to generate insights relating to the throughput and quality of mapping tasks.

In some embodiments, the map viewing services of map management platform 562 can be modularized and deployed as part of one or more of the platforms and systems of data center 550. For example, the AI/ML platform 554 may incorporate the map viewing services for visualizing the effectiveness of various object detection or object classification models, simulation platform 556 may incorporate the map viewing services for recreating and visualizing certain driving scenarios, remote assistance platform 558 may incorporate the map viewing services for replaying traffic incidents to facilitate and coordinate aid, ridesharing platform 560 may incorporate the map viewing services into client application 572 to enable passengers to view AV 502 in transit en route to a pick-up or drop-off location, and so on.

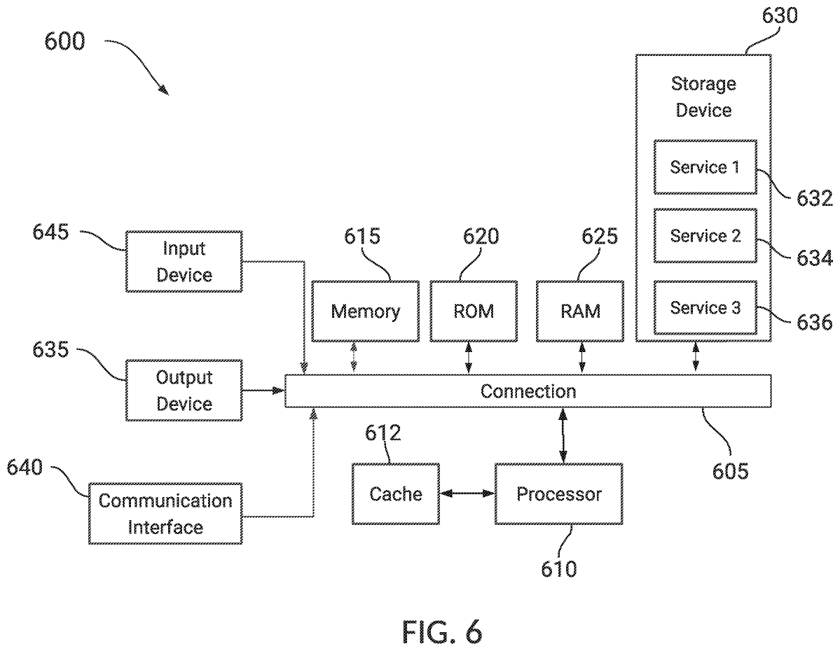

FIG. 6 illustrates an example apparatus (e.g., a processor-based system) with which some aspects of the subject technology can be implemented. For example, processor-based system 600 can be any computing device making up internal computing system 510, remote computing system 550, a passenger device executing the rideshare app 570, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

Computing system 600 can be (or may include) a distributed system in which the functions described in this disclosure can be distributed within a datacenter, multiple data centers, a peer network, etc. In some embodiments, one or more of the described system components represents many such components each performing some or all of the functions for which the component is described. In some embodiments, the components can be physical or virtual devices.

Example system 600 includes at least one processing unit (CPU or processor) 610 and connection 605 that couples various system components including system memory 615, such as read-only memory (ROM) 620 and random-access memory (RAM) 625 to processor 610. Computing system 600 can include a cache of high-speed memory 612 connected directly with, in close proximity to, or integrated as part of processor 610.

Processor 610 can include any general-purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 includes an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communications interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communication interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a Blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L5/L6), resistive random-access memory (RRAM/ReRAM), phase change memory (PCM), spin transfer torque RAM (STT-RAM), another memory chip or cartridge, and/or a combination thereof.

Storage device 630 can include software services, servers, services, etc., that when the code that defines such software is executed by the processor 610, it causes the system to perform a function. In some embodiments, a hardware service that performs a particular function can include the software component stored in a computer-readable medium in connection with the necessary hardware components, such as processor 610, connection 605, output device 635, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

Illustrative examples of the disclosure include:

Aspect 1: An apparatus comprising: at least one memory; and at least one processor coupled to the at least one memory, the at least one processor configured to: receive a set of divergence metrics, wherein the divergence metrics comprise performance statistics for one or more components of a simulation renderer; provide the divergence metrics to a machine-learning model, wherein the machine-learning model is trained to predict an autonomous vehicle (AV) pose divergence in a simulated environment based on the divergence metrics; and identify, using an attribution tool, one or more components of the simulation renderer that contributed to the AV pose divergence based on one or more weights of the machine-learning model.

Aspect 2; The apparatus of aspect 1, wherein the divergence metrics are received from the one or more components of the simulation renderer.

Aspect 3: The apparatus of aspects 1-2, wherein the machine-machine learning model comprises a regression model, a random forest, a classifier, a decision tree, or a combination thereof.

Aspect 4: The apparatus of aspects 1-3, wherein the AV pose divergence comprises a distance between a first trajectory for an AV that is represented in road data and a second trajectory for the AV that is represented in a simulated environment.

Aspect 5: The apparatus of aspects 1-4, wherein the one or more components of the simulation renderer comprises a sensor component, and wherein the sensor component is configured to simulate on or more real-world autonomous vehicle (AV) sensors in the simulated environment.

Aspect 6: The apparatus of aspects 1-5, wherein the one or more components of the simulation renderer comprises an atmospherics component that is configured to simulate atmospheric weather events in the simulated environment.

Aspect 7: The apparatus of aspects 1-6, wherein the performance statistics for one or more components of the simulation renderer are based on road data comprising one or more of: Light Detection and Ranging (LiDAR) data, Radio Detection and Ranging (RADAR) data, camera image data, or a combination thereof.

Aspect 8: A computer-implemented method, comprising: receiving a set of divergence metrics, wherein the divergence metrics comprise performance statistics for one or more components of a simulation renderer; providing the divergence metrics to a machine-learning model, wherein the machine-learning model is trained to predict an autonomous vehicle (AV) pose divergence in a simulated environment based on the divergence metrics; and identifying, using an attribution tool, one or more components of the simulation renderer that contributed to the AV pose divergence based on one or more weights of the machine-learning model.

Aspect 9: The computer-implemented method of aspect 8, wherein the divergence metrics are received from the one or more components of the simulation renderer.

Aspect 10: The computer-implemented method of aspects 8-9, wherein the machine-machine learning model comprises a regression model, a random forest, a classifier, a decision tree, or a combination thereof.

Aspect 11: The computer-implemented method of aspects 8-10, wherein the AV pose divergence comprises a distance between a first trajectory for an AV that is represented in road data and a second trajectory for the AV that is represented in a simulated environment.

Aspect 12: The computer-implemented method of aspects 8-11, wherein the one or more components of the simulation renderer comprises a sensor component, and wherein the sensor component is configured to simulate one or more real-world autonomous vehicle (AV) sensors in the simulated environment.

Aspect 13: The computer-implemented method of aspects 8-12, wherein the one or more components of the simulation renderer comprises an atmospherics component that is configured to simulate atmospheric weather events in the simulated environment.

Aspect 14: The computer-implemented method of aspects 8-13, wherein the performance statistics for one or more components of the simulation renderer are based on road data comprising one or more of: Light Detection and Ranging (LiDAR) data, Radio Detection and Ranging (RADAR) data, camera image data, or a combination thereof.

Aspect 15: A non-transitory computer-readable storage medium comprising at least one instruction for causing a computer or processor to: receive a set of divergence metrics, wherein the divergence metrics comprise performance statistics for one or more components of a simulation renderer; provide the divergence metrics to a machine-learning model, wherein the machine-learning model is trained to predict an autonomous vehicle (AV) pose divergence in a simulated environment based on the divergence metrics; and identify, using an attribution tool, one or more components of the simulation renderer that contributed to the AV pose divergence based on one or more weights of the machine-learning model.

Aspect 16: The non-transitory computer-readable storage medium of aspect 15, wherein the divergence metrics are received from the one or more components of the simulation renderer.

Aspect 17: The non-transitory computer-readable storage medium of aspects 15-16, wherein the machine-machine learning model comprises a regression model, a random forest, a classifier, a decision tree, or a combination thereof.

Aspect 18: The non-transitory computer-readable storage medium of aspects 15-17, wherein the AV pose divergence comprises a distance between a first trajectory for an AV that is represented in road data and a second trajectory for the AV that is represented in a simulated environment.

Aspect 19: The non-transitory computer-readable storage medium of aspects 15-18, wherein the one or more components of the simulation renderer comprises a sensor component, and wherein the sensor component is configured to simulate one or more real-world autonomous vehicle (AV) sensors in the simulated environment.

Aspect 20: The non-transitory computer-readable storage medium of aspects 15-19, wherein the one or more components of the simulation renderer comprises an atmospherics component that is configured to simulate atmospheric weather events in the simulated environment.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. An apparatus comprising:
at least one memory; and
at least one processor coupled to the at least one memory, the at least one processor configured to:
receive a set of divergence metrics, wherein the divergence metrics comprise performance statistics for one or more components of a simulation renderer;
provide the divergence metrics to a machine-learning model, wherein the machine-learning model is trained to predict an autonomous vehicle (AV) pose divergence in a simulated environment based on the divergence metrics; and
identify, using an attribution tool, one or more components of the simulation renderer that contributed to the AV pose divergence based on one or more weights of the machine-learning model.

2. The apparatus of claim 1, wherein the divergence metrics are received from the one or more components of the simulation renderer.

3. The apparatus of claim 1, wherein the machine-machine learning model comprises a regression model, a random forest, a classifier, a decision tree, or a combination thereof.

4. The apparatus of claim 1, wherein the AV pose divergence comprises a distance between a first trajectory for an AV that is represented in road data and a second trajectory for the AV that is represented in a simulated environment.

5. The apparatus of claim 1, wherein the one or more components of the simulation renderer comprises a sensor component, and wherein the sensor component is configured to simulate on or more real-world autonomous vehicle (AV) sensors in the simulated environment.

6. The apparatus of claim 1, wherein the one or more components of the simulation renderer comprises an atmospherics component that is configured to simulate atmospheric weather events in the simulated environment.

7. The apparatus of claim 1, wherein the performance statistics for one or more components of the simulation renderer are based on road data comprising one or more of: Light Detection and Ranging (LiDAR) data, Radio Detection and Ranging (RADAR) data, camera image data, or a combination thereof.

8. A computer-implemented method, comprising:
receiving a set of divergence metrics, wherein the divergence metrics comprise performance statistics for one or more components of a simulation renderer;
providing the divergence metrics to a machine-learning model, wherein the machine-learning model is trained to predict an autonomous vehicle (AV) pose divergence in a simulated environment based on the divergence metrics; and
identifying, using an attribution tool, one or more components of the simulation renderer that contributed to the AV pose divergence based on one or more weights of the machine-learning model.

9. The computer-implemented method of claim 8, wherein the divergence metrics are received from the one or more components of the simulation renderer.

10. The computer-implemented method of claim 8, wherein the machine-machine learning model comprises a regression model, a random forest, a classifier, a decision tree, or a combination thereof.

11. The computer-implemented method of claim 8, wherein the AV pose divergence comprises a distance between a first trajectory for an AV that is represented in road data and a second trajectory for the AV that is represented in a simulated environment.

12. The computer-implemented method of claim 8, wherein the one or more components of the simulation renderer comprises a sensor component, and wherein the sensor component is configured to simulate one or more real-world autonomous vehicle (AV) sensors in the simulated environment.

13. The computer-implemented method of claim 8, wherein the one or more components of the simulation renderer comprises an atmospherics component that is configured to simulate atmospheric weather events in the simulated environment.

14. The computer-implemented method of claim 8, wherein the performance statistics for one or more components of the simulation renderer are based on road data comprising one or more of: Light Detection and Ranging (LiDAR) data, Radio Detection and Ranging (RADAR) data, camera image data, or a combination thereof.

15. A non-transitory computer-readable storage medium comprising at least one instruction for causing a computer or processor to:
receive a set of divergence metrics, wherein the divergence metrics comprise performance statistics for one or more components of a simulation renderer;
provide the divergence metrics to a machine-learning model, wherein the machine-learning model is trained to predict an autonomous vehicle (AV) pose divergence in a simulated environment based on the divergence metrics; and
identify, using an attribution tool, one or more components of the simulation renderer that contributed to the AV pose divergence based on one or more weights of the machine-learning model.

16. The non-transitory computer-readable storage medium of claim 15, wherein the divergence metrics are received from the one or more components of the simulation renderer.

17. The non-transitory computer-readable storage medium of claim 15, wherein the machine-machine learning model comprises a regression model, a random forest, a classifier, a decision tree, or a combination thereof.

18. The non-transitory computer-readable storage medium of claim 15, wherein the AV pose divergence comprises a distance between a first trajectory for an AV that is represented in road data and a second trajectory for the AV that is represented in a simulated environment.

19. The non-transitory computer-readable storage medium of claim 15, wherein the one or more components of the simulation renderer comprises a sensor component, and wherein the sensor component is configured to simulate one or more real-world autonomous vehicle (AV) sensors in the simulated environment.

20. The non-transitory computer-readable storage medium of claim 15, wherein the one or more components of the simulation renderer comprises an atmospherics component that is configured to simulate atmospheric weather events in the simulated environment.
